(19) United States
(12) Patent Application Publication
(10) Pub. No.: US 2007/0166872 A1
(43) Pub. Date: Jul. 19, 2007

(54) Process for producing thin photosensitized semiconducting films

(76) Inventors: Philippe Prene, Tours (FR); Philippe Belleville, Tours (FR); Pelagie Declerck, Ballan-Mire (FR)

Correspondence Address: MCKENNA LONG & ALDRIDGE LLP, 1900 K STREET, NW, WASHINGTON, DC, 20006, US

(21) Appl. No.: 11/578,130

(22) PCT Filed: Apr. 21, 2005
(86) PCT No.: PCT/FR05/50268

§ 371 Date: Oct. 10, 2006

(30) Foreign Application Priority Data
Apr. 22, 2004 (FR) 0450762

(51) Int. Cl. H01L 51/40

(52) U.S. Cl. 438/99

(57) ABSTRACT

The invention relates to a process for producing thin, semiconducting films photosensitized by one or more chromophores, which comprises at least one cycle comprising, in succession, the following steps: a) a step of depositing, on a support, at least one film of a solution obtained by sol-gel polymerization of one or more precursors of a semiconducting oxide or semiconducting oxides, said semiconducting oxide or oxides being chosen from metal oxides, metalloid oxides and mixtures thereof; b) a drying step carried out on the film obtained at a); c) an acid, basic or neutral treatment step carried out in liquid or gaseous medium on the film obtained at b); and d) a step of photosensitizing the film obtained at c) by one or more chromophores, by bringing this film into contact with a solution containing the chromophore(s). Application to the production of electrodes for photovoltaic cells and to light-emitting diodes.

### TECHNICAL FIELD

The present invention relates to a process for producing thin photosensitized semiconducting films.

Such thin films are applicable as electrodes of photovoltaic cells or else in light-emitting diodes.

### PRIOR ART

Currently, thin semiconducting films, such as those made of titanium dioxide, are obtained by the deposition of a film comprising a colloidal solution of a metal oxide or oxide precursors on a support followed by a densification step carried out on the film at a high temperature, namely at a temperature of 400° C. or higher.

After a high-temperature densification step, it proves difficult for the thin films obtained to be photosensitized with chromophores owing to a surface state obtained after densification that is not very favorable to the adsorption or chemisorption of such chromophores.

### SUMMARY OF THE INVENTION

The object of the present invention is specifically to provide a process for producing thin semiconducting films, which makes it possible to obtain thin films that are conducive to photosensitization by chromophores and have satisfactory adhesion to a support.

For this purpose, the subject of the invention is a process for producing thin, semiconducting films photosensitized by one or more chromophores, which comprises at least one cycle comprising, in succession, the following steps:

a) a step of depositing, on a support, at least one film of a solution obtained by sol-gel polymerization of one or more precursors of a semiconducting oxide or semiconducting oxides, said semiconducting oxide or oxides being chosen from metal oxides, metalloid oxides and mixtures thereof;

b) a drying step carried out on the film obtained at a);

c) an acid, basic or neutral treatment step carried out in liquid or gaseous medium on the film obtained at b); and

d) a step of photosensitizing the film obtained at c) by one or more chromophores, by bringing this film into contact with a solution containing the chromophore(s).

It should be pointed out that the term “thin film” is understood to mean within the invention a film having a thickness of less than 1 mm.

Thanks to this process having step c), a film is obtained that has a surface state favorable to photosensitization by chromophores. Specifically, thanks to this treatment step, the surface state is such that it allows the amount of chromophores deposited on the surface of the film to be increased and consequently, the solar absorption efficiency of such films is increased when they are used as electrodes in photovoltaic devices.

In addition, this process is a process simple to implement and of low cost.

As mentioned above, the process of the invention includes a first step consisting in covering a surface of a support with at least one film of a solution obtained by sol-gel polymerization of one or more precursors of a semiconducting oxide or semiconducting oxides, said semiconducting oxide(s) being chosen from metal oxides, metalloid oxides and mixtures thereof.

Preferably, the support is a translucent support, especially when the thin films are intended to be used in photovoltaic devices.

The term “translucent support” is understood to mean in the invention, an organic or inorganic support that lets light pass through it but does not allow objects placed behind it to be clearly distinguished. The term “organic support” is understood to mean according to the invention a plastic support, for example made of a polymer chosen from polyacrylates, polycarbonates, polyallyl carbonates, polymethyl methacrylates and polyamides. The term “inorganic support” is understood to mean according to the invention, a glassy support, that is to say a support made of an amorphous or crystalline material such as silica, borosilicate glass and soda-lime glass.

The term “metal oxide” is understood to mean according to the invention an oxide containing one or more metallic elements in its crystal lattice. These metallic elements may be transition metals or lanthanide metals, such as those defined below. The transition metal element may be chosen from Ti, V, Cr, Mn, Fe, Co, Ni, Cu, Zn, Y, Zr, Nb, Mo, Ru, Rh, Pd, Ag, Cd, Hf, Ta, W, Re, Os, Ir and Pt. The lanthanide element may be chosen from La, Ce, Pr, Nd, Sm, Eu, Gd, Tb, Dy, Er and Yb. The metallic elements may also be “post-transition” metals, such as those belonging to column IIIA (Al, Ga, In, Tl) and column IVA (Ge, Sn, Pb) of the Periodic Table of Elements.

The term “metalloid oxide” is understood within the invention to mean an oxide containing one or more metalloid elements in its crystal lattice, said metalloid elements being chosen from Si, Se and Te.

The term “oxide precursors” is understood according to the invention to mean alkoxide compounds of formula M(OR)ₙ where M represents a metallic element or a metalloid element as defined above, R represents an alkyl group containing 1 to 6 carbon atoms, n represents the valency of the metallic element or metalloid element, it being possible for the alkoxide to be replaced with a mineral precursor (a metal salt) or any other molecular precursor of a metal or metalloid element that can be hydrolyzed.

According to the invention, the solution deposited on the support is obtained using the technique of “sol-gel” (standing for solution-gelation) polymerization.

Using this sol-gel technique, the abovementioned solution is synthesized, generally by mixing one or more precursors as defined above in a medium comprising at least one organic or aqueous solvent followed by complete or partial hydrolysis of said precursors and by condensation of said precursors thus hydrolyzed.

The organic solvent or solvents into which the semiconducting oxide precursors are mixed are generally alcoholic solvents, in particular aliphatic alcohols, such as ethanol or isopropanol.

The precursors are generally hydrolyzed by adding an aqueous (acid, basic or neutral) solution to the mixture. Once hydrolyzed, the precursors have reactive groups such as —OH groups, capable of condensing during a condensation step after which the solution contains chemical species in the form of oligomers, polymers or colloids.

A person skilled in the art will choose, according to the nature of the precursors, the conditions (pH, amount of added water, etc.) for hydrolyzing these precursors in order to obtain chemical species in the solution that are in the form of oligomers, polymers and/or colloids.

In particular, when the solution to be deposited on the support is a colloidal oxide solution, the solution to be deposited is prepared according to the following steps:

a mixing step, in which an oxide precursor (such as an alkoxide or a salt) is mixed into a solvent, preferably an organic solvent (for example an alcohol, such as isopropanol); and

an addition step with stirring, in which the resulting mixture is added to an acid, basic or neutral aqueous solution, on completion of which step, after a suitable stirring time, a colloidal semiconducting oxide solution is obtained, it being possible for the addition step to be reversed (namely the addition of the aqueous solution to the mixture resulting from the first step).

In general, the colloidal solution comprises oxide colloids dispersed in the liquid medium (organic solvent+aqueous solution) that have a diameter of about 1 to 100 nm in diameter.

When the thin film is made of titanium dioxide, a suitable precursor may be a titanium alkoxide such as titanium tetraisopropoxide or a titanium salt such as titanium tetrachloride.

In this situation, the solution to be deposited on the support is generally prepared by bringing the titanium precursor into contact with an alcoholic medium (such as isopropanol) followed by hydrolysis of said precursor by the addition of an aqueous acid solution (such as an aqueous hydrochloric acid solution) or an aqueous basic solution (such as a tetraethylammonium hydroxide solution).

Once prepared by the preparation explained above, the solution is deposited on a support, possibly a translucent support.

The deposition may be performed by one of the following techniques:

dip-coating;

spin-coating;

laminar-flow coating or meniscus coating;

spray coating;

soak coating;

roll-to-roll coating;

brush coating;

screen printing.

Such a deposition step is shown in FIGS. 1 and 2. As illustrated in these figures, a film 3 of a solution as defined above is deposited on a translucent support 1.

It should be pointed out that the translucent support may include, on one of its faces a transparent conducting film, for example a film based on fluorine-doped tin oxide of based on tin-doped indium oxide, and a semiconducting dense film, for example made of titanium dioxide. The film of solution is deposited in this situation on the aforementioned films. The transparent conducting film in the case of a photovoltaic cell will constitute a working electrode. The dense titanium dioxide film will constitute a screen film between the transparent conducting film and the thin film acting as porous counter electrode obtained by the process of the invention.

It should be noted that the support may be cleaned before the deposition step, for example using dilute hydrofluoric acid and/or a detergent solution.

After the deposition step, the process of the invention includes a drying step so that the solvent or solvents used in step a) evaporate.

Before the acid, basic or neutral treatment, the process of the invention may include a chemical washing step intended to remove the organic residues resulting from the solution deposited during the first step of the process, such as the residues resulting from the hydrolysis of the abovementioned precursors.

The process of the invention may also include before treatment step c), a step in which the film is heat treated, this heat treatment step advantageously consisting in heating the film to a temperature ranging from 30 to 450° C. This heat treatment step is intended, in particular to densify the deposited film.

The process includes as mentioned above, either directly after the drying step or where appropriate before the washing step and/or the heat treatment step an acid, basic or neutral treatment step carried out in liquid or gaseous medium on the deposited film.

In other words, this step consists in bringing the deposited film into contact with:

an acid, basic or neutral solution when the treatment takes place in a liquid medium; or

acid, basic or neutral vapors when the treatment takes place in a gaseous medium.

FIGS. 3 and 4 show two methods for implementing the treatment in gaseous medium.

In FIG. 3, the support 1 coated with a film 3 is placed in a closed vessel 5 into which acid, basic or neutral vapors 9 are injected via an orifice 7.

In FIG. 4, the support 1 coated with a film 3 is placed on a substrate 11 inside a closed vessel 5, while an acid, basic or neutral solution 13 is placed in the bottom of the vessel so as to produce acid, basic or neutral vapors 15.

FIG. 5 shows a method of implementing the treatment in an aqueous medium.

In this figure, the support 1 coated with the film 3 is immersed in an acid, basic or neutral solution 17.

In the case of an acid treatment carried out in gaseous phase, the acid vapors to which the deposited film is exposed may be vapors of mineral acids chosen from hydrochloric acid (HCl), hydrofluoric acid (HF), nitric acid (HNO₃), orthoboric acid (H₃BO₃), orthophosphoric acid (H₃PO₄), perchloric acid (HClO₄) and sulfuric acid (H₂SO₄). Preferably, the acid vapors are hydrochloric acid vapors.

In the case of an acid treatment carried out in liquid phase, the acid solutions to which the deposited film is exposed may be mineral acid solutions such as hydrochloric acid (HCl), hydrofluoric acid (HF), nitric acid (HNO₃), orthoboric acid (H₃BO₃), orthophosphoric acid (H₃PO₄), perchloric acid (HClO₄) and sulfuric acid (H₂SO₄) solutions or mixtures thereof.

These solutions are generally aqueous solutions, but they may be organic solutions obtained by mixing an aqueous mineral acid solution into an organic solvent. The organic solvent may be an aliphatic alcohol solvent.

The acid solutions may also be solutions of organic acids, such as carboxylic acids of formula RCOOH, in which R represents an alkyl group containing 1 to 30 carbon atoms or a phenyl group, such as oxalic acid C₂H₂O₄.

It should be pointed out that the organic acid solutions preferably comprise non dissociating solvents, that is to say those having a low dielectric constant. Such solvents may be, for example, aliphatic alcohols such as ethanol.

In the case of basic treatment carried out in gaseous medium, the basic vapors to which the deposited film is exposed may advantageously be ammonia vapors.

In the case of a basic treatment carried out in liquid medium, the basic solutions may be solutions of a mineral base, such as sodium hydroxide (NaOH), potassium hydroxide (KOH), tetraethylammonium hydroxide (N(CH₃)₄OH) and ammonium hydroxide (NH₄OH) solutions, or solutions of an organic base such as hydroxylamine (NH₂OH) and diethanolamine (NH(CH₂OHCH₂)₂).

In general, the mineral base solutions are aqueous solutions, whereas the organic base solutions are organic solutions preferably containing non dissociating solvents as defined above.

In general, whether for an acid treatment or a basic treatment, the acid or base concentration is between 1 and 50% by weight of the total weight of the treatment solution.

Finally, in the case of a neutral treatment carried out in liquid phase, the neutral solutions may be solutions of aliphatic alcohols, such as ethanol, or water/aliphatic alcohol mixtures, whereas in the case of a neutral treatment carried out in gaseous phase, the neutral vapors are aliphatic alcohol vapors or vapors of water/aliphatic alcohol mixtures.

Whatever the envisaged treatment (acid, basic or neutral treatment), the duration of this treatment is advantageously between 1 and 24 hours at a temperature that may range from room temperature up to a temperature of around 100° C.

At the end of the acid basic or neutral treatment step, a thin semiconducting oxide film is obtained.

It has been shown that, after the acid, basic or neutral treatment, the film withstood physical contact, that is to say it could be handled with gloves and could also stand being wiped several times with optical paper soaked with alcohol (according to the drag-wipe test) without degrading the film.

This thin film may be a mesoporous film, optionally one that is mesostructured.

It should be noted that the term “mesoporous” film is understood to mean a film characterized by a high porosity, the pore sizes ranging from 2 to 80 nm and with walls a few nanometers in thickness. In general, the pores are distributed randomly with a very broad pore size distribution, within the abovementioned range.

It should be noted that the term “mesostructured” film is understood to mean a mesoporous film in the form of organized porous networks having an ordered spatial arrangement of mesopores. This spatial periodicity of pores is characterized by the appearance of at least one peak at a low angle in an X-ray scattering diagram. This peak is associated with a repeat distance of generally between 2 and 50 nm.

When the metal oxide is titanium dioxide, the titanium dioxide may be in the form of an optionally mesostructured, mesoporous nanocrystalline titanium dioxide (anatase, rutile or brookite).

The term “nanocrystalline titanium dioxide” is understood to mean titanium dioxide having crystallites of the order of a few nanometers, for example 2 to 200 nm.

Finally, the process of the invention includes, after the acid, basic or neutral treatment step, a sensitization step in which the semiconducting oxide film obtained after the treatment is sensitized with chromophores.

It should be pointed out that, according to the invention, the term “chromophore” is understood to mean a substance capable of absorbing light in the IR, UV and visible ranges and of releasing electrons in return for this absorption.

In general, this sensitization step is carried out by immersing the support coated with the thin semiconducting oxide film in a solution containing the chromophore or chromophores, said chromophore(s) comprising one or more groups capable of being attached to the oxide film. Such groups may be carboxylate groups, acetylacetonate groups, cyano groups, phosphate groups, chelating groups having a π conduction character, chosen from oximes, dioximes, hydroxyquinolines, salicylates, and α-ketoenolates.

Such chromophores may be substances chosen from ruthenium complexes such as for example cis-bis(isothiocyanato)bis(2,2′-bipyridyl-4,4′-dicarboxylato) ruthenium (II) (sold by Solaronix under the reference Ruthenium 535-bis TBA).

It is possible to carry out a single cycle comprising the deposition of the film, the drying, the treatment and the sensitization but it is also possible to carry out several successive cycles.

### BRIEF DESCRIPTION OF THE DRAWINGS

FIGS. 1 to 5 illustrate various steps in the production process according to the invention.

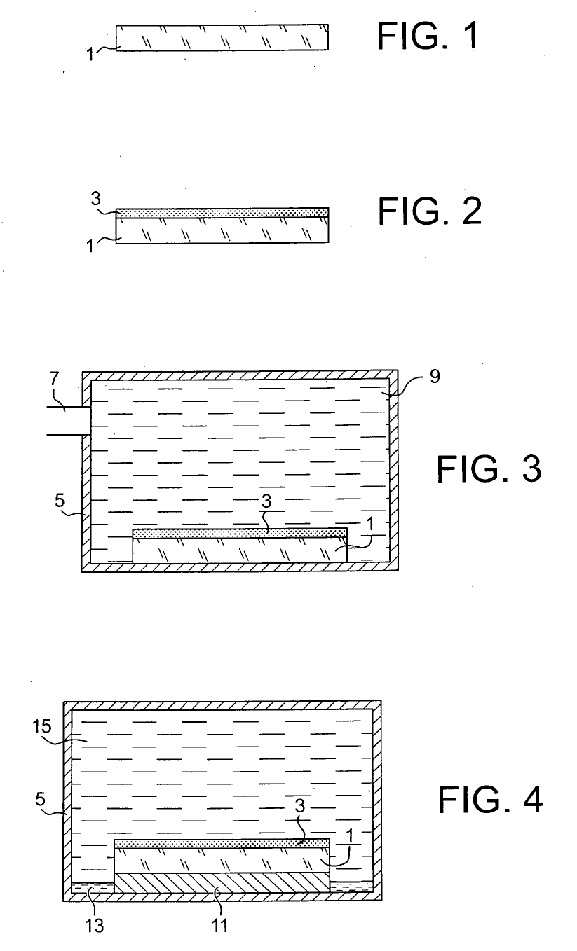

FIG. 6 is a graph illustrating the absorption (with the symbol Abs) in arbitrary units as a function of the wavelength (λ, in nm) of a film that has undergone a heat treatment according to the prior art (the dotted curve) at and of a film that has undergone an acid treatment according to the invention (the solid curve).

### DETAILED DESECRIPTION OF PARTICULAR EMBODIMENTS

The invention will now be described with regard to the following exemplary embodiment.

a) Preparation of the Support

Within the context of this example, the transparent support was a rectangular (1×5 cm) support made of borosilicate glass (type BK-7 manufactured by the company Schott) with a thickness of 2 mm. The refractive index was 1.52 at a wavelength of 600 nm. It was neither coated with a transparent conducting film nor with any dense semiconducting film so as to eliminate the optical perturbations induced by their presence on the surface on the support. The transparent support was firstly cleaned according to the following procedure. The cleaning of the surface is intended to be coated was carried out with a dilute (1 vol %) hydrofluoric acid solution. Next, this surface was rinsed with deionized pure water and cleaned using a detergent solution of vegetable soap (called “Green Soap”, from Eli Lilly Co.). Finally this surface was rinsed with deionized pure water and then dried with ethyl alcohol.

b) Preparation and Deposition of the Film of Solution

A colloidal solution of titanium oxide TiO₂ was prepared by adding, drop by drop, a solution of titanium tetraisopropoxide (0.5 g) dissolved in 7.85 g of isopropanol to 100 ml of a solution of dilute hydrochloric acid (pH=1.5) with vigorous stirring. The mixture was kept stirred by magnetic stirring for 12 hours. The transmission electron microscopy observations showed a mean colloid diameter of about 10 nm. The X-ray diagram was characteristic of that of titanium oxide in anatase form. The pH of this sol was about 2 and the mass concentration of TiO₂ was brought to 10% by distillation (100° C.; 10⁵ Pa). Before being used, the colloidal titanium oxide solution was filtered at 0.45 μm.

The film of colloidal titanium oxide solution was deposited by spin coating at 500 revolutions per minute on one face of the support cleaned as described above. The film was dried for 5 minutes while rotating.

c) Treatment of the Support

The support coated with the dried titanium oxide film was placed with the coated face uppermost on a substrate placed on the bottom of a closed vessel with a volume of 10 dm³, containing about 500 cm³ of 37 wt % fuming hydrochloric acid. The 37 wt % fuming hydrochloric acid solution corresponded to a standard commercial solution. The support and the titanium oxide film were kept in confinement for a minimum of 12 hours.

The support coated with the titanium oxide film was then removed from the vessel and immersed in a solution containing a ruthenium-based chromophore (Ruthenium 535-bis TBA manufactured by Solaronix) dispersed in an ethanol medium (0.025 wt %). The support and the titanium oxide film were kept in contact with the chromophore for a minimum of 4 hours.

d) Results

The properties resulting from this treatment were the following:

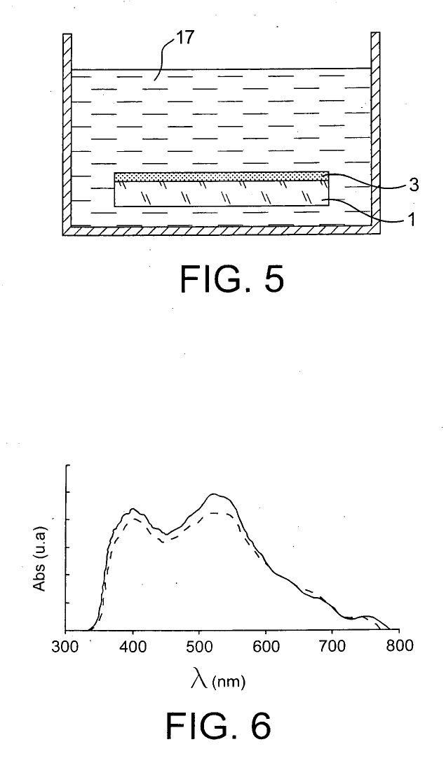

a spectral absorption induced by the ruthenium-based chromophore (as shown in FIG. 6) present on the surface of the titanium dioxide film treated with the acid vapors for 12 hours was maintained at the level of that of an identical film that had undergone a sintering operation by heat treatment at 400° C. for 10 minutes. At the wavelength corresponding to the maximum absorption of the chromophore (525 nm), the acid vapor treatment even results in an increase in the absorption of the photosensitized titanium dioxide film;

the mechanical abrasion resistance of the film and the improved adhesion properties between the film and the support allowing physical contact with the treated surface.

1. A process for producing thin, semiconducting films photosensitized by one or more chromophores, which comprises at least one cycle comprising, in succession, the following steps:
a) a step of depositing, on a support, at least one film of a solution obtained by sol-gel polymerization of one or more precursors of a semiconducting oxide or semiconducting oxides, said semiconducting oxide or oxides being chosen from metal oxides, metalloid oxides and mixtures thereof;
b) a drying step carried out on the film obtained at a);
c) an acid, basic or neutral treatment step carried out in liquid or gaseous medium on the film obtained at b); and
d) a step of photosensitizing the film obtained at c) by one or more chromophores, by bringing this film into contact with a solution containing the chromophore(s).

2. The process as claimed in claim 1, in which the support is a translucent support.

3. The process as claimed in claim 1, in which the metal oxide or oxides are chosen from transition metal oxides, lanthanide metal oxides, and post-transition metal oxides.

4. The process as claimed in claim 3, in which the transition metal oxide or oxides are chosen from the oxides of Ti, V, Cr, Mn, Fe, Co, Ni, Cu, Zn, Y, Zr, Nb, Mo, Ru, Rh, Pd, Ag, Cd, Hf, Ta, W, Re, Os, Ir and Pt.

5. The process as claimed in claim 3, in which the lanthanide metal oxide or oxides are chosen from the oxides of La, Ce, Pr, Nd, Sm, Eu, Gd, Tb, Dy, Er and Yb.

6. The process as claimed in claim 3, in which the metalloid oxide or oxides are chosen from the oxides of Si, Se and Te.

7. The process as claimed in claim 1, in which the semiconducting oxide precursor or precursors are chosen from alkoxides of formula M(OR)ₙ where M represents a metal or a metalloid, R represents an alkyl group containing 1 to 6 carbon atoms, and n represents the valency of the metal or metalloid.

8. The process as claimed in claim 1, in which the semiconducting oxide is titanium dioxide.

9. The process as claimed in claim 1, in which the treatment in gaseous medium is carried out by bringing the film obtained at b) into contact with acid, basic or neutral vapors.

10. The process as claimed in claim 9, in which the acid vapors are hydrochloric acid vapors.

11. The process as claimed in claim 9, in which the basic vapors are ammonia vapors.

12. The process as claimed in claim 9, in which the neutral vapors are aliphatic alcohol vapors.

13. The process as claimed in claim 1, in which the treatment in liquid medium is carried out by bringing the film obtained at b) into contact with an acid, basic or neutral solution.

14. The process as claimed in claim 13, in which the acid solution is a mineral acid solution chosen from hydrochloric acid (HCl), hydrofluoric acid (HF), nitric acid (HNO₃), orthoboric acid (H₃BO₃), orthophosphoric acid (H₃PO₄), perchloric acid (HClO₄), sulfuric acid (H₂SO₄) solutions and mixtures thereof.

15. The process as claimed in claim 13, in which the acid solution is a solution of an organic acid of formula RCOOH, in which R represents an alkyl group containing 1 to 30 carbon atoms or a phenyl group.

16. The process as claimed in claim 13, in which the basic solution is a mineral base solution chosen from sodium hydroxide (NaOH), potassium hydroxide (KOH), and ammonium hydroxide solutions.

17. The process as claimed in claim 13, in which the basic solution is an organic base solution chosen from hydroxylamine (NH₂OH) and diethanolamine (NH(CH₂OHCH₂)₂).

18. The process as claimed in claim 1, in which the duration of treatment step c) is between 1 and 24 hours.

19. The process as claimed in claim 1, in which the chromophore or chromophores are ruthenium complexes.

20. The process as claimed in claim 1, which further includes, before the acid, basic or neutral treatment step, a heat treatment step.

21. The process as claimed in claim 1, in which the thin film is a mesoporous film, optionally one that is mesostructured.
